(19) United States
(12) Patent Application Publication
(10) Pub. No.: US 2026/0047277 A1
(43) Pub. Date: Feb. 12, 2026

(54) DISPLAY DEVICE AND ELECTRONIC DEVICE INCLUDING THE SAME

(71) Applicant: Samsung Display Co., Ltd., Yongin-si (KR)

(72) Inventors: Changkyu Jin, Yongin-si (KR); Minki Yang, Yongin-si (KR); Daehyun Kim, Yongin-si (KR); Hyojoon Song, Yongin-si (KR); Heyjin Shin, Yongin-si (KR); Hwansoo Jang, Yongin-si (KR)

(21) Appl. No.: 19/293,454

(22) Filed: Aug. 7, 2025

(30) Foreign Application Priority Data
Aug. 7, 2024 (KR) 10-2024-0105707

(51) Int. Cl. H10K 59/121; H10K 59/131

(52) U.S. Cl. CPC H10K 59/1213; H10K 59/131

(57) ABSTRACT

A display device includes a substrate including a first and second pixel circuit area adjacent to each other; a pixel circuit on the substrate and including a first pixel circuit in the first pixel circuit area, a second pixel circuit in the second pixel circuit area; and a light-emitting element connected to the pixel circuit, wherein each of the pixel circuits includes: a first transistor connected to a driving voltage line and the light-emitting element and for supplying current to the light-emitting element; a second transistor connected to a data line and the first transistor; a third transistor connected to a gate and terminal of the first transistor; and a fourth transistor connected to the gate of the first transistor and a first initialization voltage line; and the third and fourth transistors of the first pixel circuit are line-symmetrical to those the second pixel circuit.

### CROSS-REFERENCE TO RELATED APPLICATION

The present application claims priority to and the benefit of Korean Patent Application No. 10-2024-0105707, filed on Aug. 7, 2024, in the Korean Intellectual Property Office, the entire disclosure of which is incorporated herein by reference.

### BACKGROUND

### 1. Field

Aspects of embodiments of the present disclosure relate to a structure of a display device.

### 2. Description of the Related Art

A display device may include a plurality of pixels. Each of the plurality of pixels may include a light-emitting diode and a pixel circuit for controlling a brightness of the light-emitting diode. The pixel circuit may include transistors and capacitors connected to wires such as data lines, gate lines, and voltage lines.

Recently, display devices have become thinner and lighter in weight, and thus, may be applied to various electronic devices. As display devices have become widely used, various types of display devices are being designed.

The above information disclosed in this Background section is only for enhancement of understanding of the background of the invention and therefore it may contain information that does not form the prior art.

### SUMMARY

Aspects of some embodiments of the present disclosure are directed to a display device with improved display quality. However, this is merely an example, and the scope of the disclosure is not limited thereto.

Additional aspects will be set forth in part in the description which follows and, in part, will be apparent from the description, or may be learned by practice of the presented embodiments of the disclosure.

According to some embodiments of the present disclosure, there is provided a display device including: a substrate including a first pixel circuit area and a second pixel circuit area adjacent to the first pixel circuit area along a first direction; a pixel circuit on the substrate and including a first pixel circuit in the first pixel circuit area, and a second pixel circuit in the second pixel circuit area; and a light-emitting element connected to the pixel circuit, wherein each of the first pixel circuit and the second pixel circuit includes: a first transistor electrically connected to a driving voltage line and the light-emitting element and configured to control current supplied to the light-emitting element; a second transistor electrically connected to a data line and a first terminal of the first transistor; a third transistor electrically connected to a gate of the first transistor and a second terminal of the first transistor; and a fourth transistor electrically connected to the gate of the first transistor and a first initialization voltage line; and wherein, in a plan view, the third transistor of the first pixel circuit and the fourth transistor of the first pixel circuit are line-symmetrical to the third transistor of the second pixel circuit and the fourth transistor of the second pixel circuit, with respect to an imaginary straight line extending in a second direction intersecting the first direction.

In some embodiments, the driving voltage line and the data line may be arranged in each of the first pixel circuit area and the second pixel circuit area and extend along the second direction.

In some embodiments, the display device may further include: a second initialization voltage line extending along the second direction, wherein the second initialization voltage line is on a boundary between the first pixel circuit area and the second pixel circuit area, and wherein a portion of the second initialization voltage line is in the first pixel circuit area, and another portion of the second initialization voltage line is in the second pixel circuit area.

In some embodiments, the display device may further include a first gate line connected to a gate of the third transistor, wherein the first gate line includes: a first trunk portion extending along the first direction; a first branch portion branched from the first trunk portion within the first pixel circuit area and extending in the second direction; and a second branch portion branched from the first trunk portion within the second pixel circuit area and extending in the second direction.

In some embodiments, a distance from a boundary between the first pixel circuit area and the second pixel circuit area to the first branch portion may be about the same as a distance from the boundary between the first pixel circuit area and the second pixel circuit area to the second branch portion.

In some embodiments, the third transistor may include a first sub-transistor and a second sub-transistor connected in series, a gate of the first sub-transistor may be formed in a partial area of the first branch portion or a partial area of the second branch portion, and a gate of the second sub-transistor may be formed in a partial area of the first trunk portion.

In some embodiments, the display device may further include a second gate line connected to a gate of the fourth transistor, wherein the second gate line includes: a second trunk portion extending along the first direction; a third branch portion branched from the second trunk portion within the first pixel circuit area and extending in the second direction; and a fourth branch portion branched from the second trunk portion within the second pixel circuit area and extending in the second direction.

In some embodiments, a distance from a boundary between the first pixel circuit area and the second pixel circuit area to the third branch portion may be about the same as a distance from the boundary between the first pixel circuit area and the second pixel circuit area to the fourth branch portion.

In some embodiments, the fourth transistor may include a third sub-transistor and a fourth sub-transistor connected in series, a gate of the third sub-transistor may be formed in a partial area of the second trunk portion, and a gate of the fourth sub-transistor may be formed in a partial area of the third branch portion or a partial area of the fourth branch portion.

In some embodiments, the light-emitting element may include a pixel electrode, an intermediate layer on the pixel electrode, and an opposite electrode on the intermediate layer, and wherein in a plan view, the pixel electrode may overlap at least a portion of the third transistor and the fourth transistor.

In some embodiments, the light-emitting element may include a first light-emitting diode, a second light-emitting diode, and a third light-emitting diode emitting light of different colors, the first light-emitting diode and the third light-emitting diode may be arranged alternately in a first row extending in the first direction, and the second light-emitting diode may be repeatedly arranged in a second row parallel to the first row, and may be arranged between the first light-emitting diode and the third light-emitting diode with respect to the first direction.

In some embodiments, the pixel electrode that at least partially overlaps with the third transistor and the fourth transistor may be a pixel electrode of the first light-emitting diode or a pixel electrode of the third light-emitting diode.

In some embodiments, a first semiconductor layer of the first transistor, a second semiconductor layer of the second transistor, a third semiconductor layer of the third transistor, and a fourth semiconductor layer of the fourth transistor may be integrally formed.

In some embodiments, the first semiconductor layer, the second semiconductor layer, the third semiconductor layer, and the fourth semiconductor layer may include a silicon-based semiconductor material.

According to some embodiments of the present disclosure, there is provided a display device including: a substrate including a first pixel circuit area and a second pixel circuit area arranged adjacent to the first pixel circuit area along a first direction; a first gate line on the substrate and extending along the first direction; a driving voltage line extending along a second direction intersecting the first direction; a pixel circuit including a first pixel circuit in the first pixel circuit area, and a second pixel circuit in the second pixel circuit area; and a light-emitting element connected to the pixel circuit and including a pixel electrode, an intermediate layer on the pixel electrode, and an opposite electrode on the intermediate layer; wherein each of the first pixel circuit and the second pixel circuit includes: a driving transistor electrically connected to the driving voltage line and the light-emitting element; and a compensation transistor including a gate connected to the first gate line, and connected to a gate of the driving transistor and a first terminal of the driving transistor, wherein, in a plan view, the compensation transistor of the first pixel circuit and the compensation transistor of the second pixel circuit may be line-symmetrical to each other with respect to an imaginary straight line extending in the second direction, and a partial area of the pixel electrode overlaps with the compensation transistor.

In some embodiments, the display device may further include: a data line extending along the second direction; and a vertical initialization voltage line extending along the second direction, the data line and the driving voltage line may be in the first pixel circuit area and the second pixel circuit area, respectively, and the vertical initialization voltage line may be on a boundary between the first pixel circuit area and the second pixel circuit area, and may be over the first pixel circuit area and the second pixel circuit area.

In some embodiments, the first gate line may include: a first trunk portion extending along the first direction; a first branch portion branched from the first trunk portion within the first pixel circuit area and extending in the second direction; and a second branch portion branched from the first trunk portion within the second pixel circuit area and extending in the second direction.

In some embodiments, a distance from a boundary between the first pixel circuit area and the second pixel circuit area to the first branch portion may be about the same as a distance from the boundary between the first pixel circuit area and the second pixel circuit area to the second branch portion.

In some embodiments, the compensation transistor may include a first sub-transistor and a second sub-transistor connected in series, a gate of the first sub-transistor may be formed in a partial area of the first branch portion or a partial area of the second branch portion, and a gate of the second sub-transistor may be formed in a partial area of the first trunk portion.

In some embodiments, a partial area of the pixel electrode may cover both the first sub-transistor and the second sub-transistor.

In some embodiments, the display device may further include a second gate line and a horizontal initialization voltage line extending along the first direction, each of the first pixel circuit and the second pixel circuit further may include an initialization transistor including a gate connected to the second gate line and electrically connected to the gate of the driving transistor and the horizontal initialization voltage line, and in a plan view, the initialization transistor of the first pixel circuit and the initialization transistor of the second pixel circuit may be line-symmetrical to each other with respect to the imaginary straight line extending in the second direction.

In some embodiments, the second gate line may include: a second trunk portion extending along the first direction; a third branch portion branched from the second trunk portion within the first pixel circuit area and extending in the second direction; and a fourth branch portion branched from the second trunk portion within the second pixel circuit area and extending in the second direction.

In some embodiments, a distance from a boundary between the first pixel circuit area and the second pixel circuit area to the third branch portion may be about the same as a distance from the boundary between the first pixel circuit area and the second pixel circuit area to the fourth branch portion.

In some embodiments, the initialization transistor may include a third sub-transistor and a fourth sub-transistor connected in series, a gate of the third sub-transistor may be formed in a partial area of the second trunk portion, and a gate of the fourth sub-transistor may be formed in a partial area of the third branch portion or a partial area of the fourth branch portion.

In some embodiments, a partial area of the pixel electrode may cover at least one of the third sub-transistor and the fourth sub-transistor.

In some embodiments, a semiconductor layer of the driving transistor and a semiconductor layer of the compensation transistor may be formed integrally, and the semiconductor layer of the driving transistor and the semiconductor layer of the compensation transistor may include a silicon-based semiconductor material.

According to some embodiments of the present disclosure, there is provided an electronic device including: an input module configured to receive input data from a user; a memory configured to store the input data; a processor configured to perform computations based on the input data and provide output data; and a display module configured to display an image to the user based, in part, on the input data and the output data, the display module including: a substrate including a first pixel circuit area and a second pixel circuit area adjacent to the first pixel circuit area along a first direction; a pixel circuit on the substrate and including a first pixel circuit in the first pixel circuit area, and a second pixel circuit in the second pixel circuit area; and a light-emitting element connected to the pixel circuit, wherein each of the first pixel circuit and the second pixel circuit includes: a first transistor electrically connected to a driving voltage line and the light-emitting element and configured to control current supplied to the light-emitting element; a second transistor electrically connected to a data line and a first terminal of the first transistor; a third transistor electrically connected to a gate of the first transistor and a second terminal of the first transistor; and a fourth transistor electrically connected to the gate of the first transistor and a first initialization voltage line; and wherein, in a plan view, the third transistor of the first pixel circuit and the fourth transistor of the first pixel circuit are line-symmetrical to the third transistor of the second pixel circuit and the fourth transistor of the second pixel circuit, with respect to an imaginary straight line extending in a second direction intersecting the first direction.

In some embodiments, the electronic device may be a smartphone.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 illustrates a schematic plan view of a display device according to some embodiments of the present disclosure;

FIG. 2 is a conceptual diagram schematically illustrating a display device according to some embodiments of the present disclosure;

FIGS. 3A and 3B are equivalent circuit diagrams illustrating one pixel included in a display device according to some embodiments of the present disclosure;

FIG. 4 is a layout view schematically illustrating a portion of a display device according to some embodiments of the present disclosure;

FIGS. 5 to 9 are layout views each schematically illustrating a portion of the display device of FIG. 4 for each layer according to some embodiments of the present disclosure;

FIG. 10 is a layout view schematically illustrating a portion of a display device according to some embodiments of the present disclosure;

FIG. 11 is a schematic cross-sectional view illustrating a portion of a display device according to some embodiments of the present disclosure;

FIG. 12 is a block diagram of an electronic apparatus according to some embodiments of the present disclosure;

FIG. 13 is a schematic diagrams of an electronic apparatuses according to various embodiments.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

The electronic or electric devices and/or any other relevant devices or components according to embodiments of the present disclosure described herein may be implemented utilizing any suitable hardware, firmware (e.g. an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the example embodiments of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein. In the specification, the term “on” used in connection with an element state may refer to an active state of the element, and the term “off” may refer to an inactive state of the element. The term “on” used in connection with a signal received by an element may refer to a signal for activating the element, and the term “off” may refer to a signal for deactivating the element. The element may be activated by a high-level voltage or a low-level voltage. For example, a P-channel transistor (P-type transistor) is activated by a low-level voltage, and an N-channel transistor (N-type transistor) is activated by a high-level voltage. Accordingly, it should be understood that “on” voltages for the P-type transistor and the N-type transistor have opposite (high and low) voltage levels.

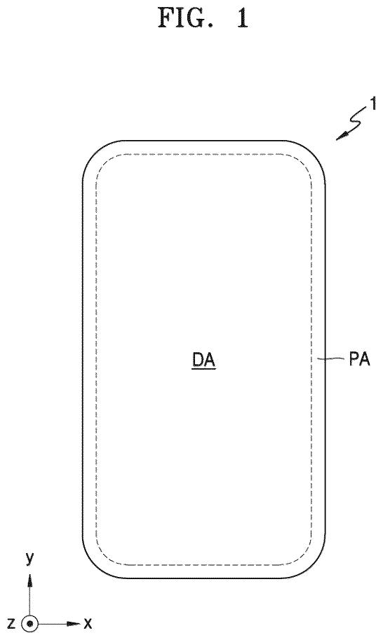

FIG. 1 illustrates a schematic plan view of a display device according to some embodiments of the present disclosure.

Referring to FIG. 1, a display device 1 may include a display area DA where an image is displayed and a peripheral area PA outside the display area DA. The display device 1 may provide a certain image by using light emitted from a plurality of pixels located in the display area DA. In some embodiments, each pixel may emit red light, green light, or blue light. In some other embodiments, each pixel may emit red light, green light, blue light, or white light.

In a plan view, the display area DA may have a quadrangular shape. In some other embodiments, the display area DA may have another polygonal shape, a circular shape, an elliptical shape, or an irregular shape. The display area DA may have a shape with round corners or square corners.

In some embodiments, the display area DA of the display device 1 may have a length in a first direction (e.g., a x direction) that is less than a length in a second direction (e.g., a y direction). In some other embodiments, the display area DA of the display device 1 may have a length in the first direction (e.g., the x direction) that is greater than a length in the second direction (e.g., the y direction).

The peripheral area PA may be located around the display area DA and may surround at least a part of the display area DA. In some embodiments, the peripheral area PA may be a non-display area where pixels are not located. Various wiring for transmitting electric signals to be applied to the display area DA, circuits, and pads to which a printed circuit board or a driver integrated circuit (IC) chip is attached may be located in the peripheral area PA.

Although the display device 1 according to some embodiments may be an organic light-emitting display device including an organic light-emitting diode, the display device of the disclosure is not limited thereto. In some other embodiments, the display device 1 of the disclosure may include an inorganic light-emitting diode or may include a quantum dot light-emitting diode.

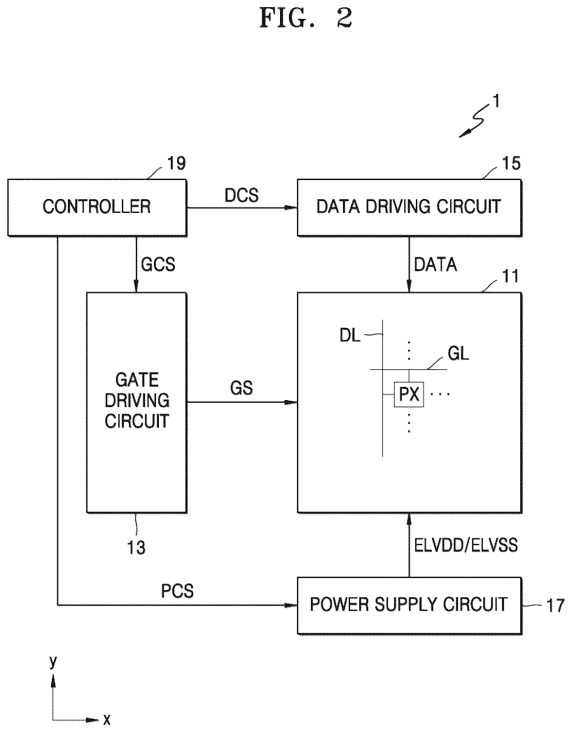

FIG. 2 is a conceptual diagram schematically illustrating a display device according to some embodiments of the present disclosure.

Referring to FIG. 2, the display device 1 according to some embodiments may include a pixel area 11, a gate driving circuit 13, a data driving circuit 15, a power supply circuit 17, and a controller 19.

The pixel area 11 may correspond to the display area DA (see, e.g., FIG. 1). As shown in FIG. 2, a plurality of gate lines GL, a plurality of data lines DL, and a plurality of pixels PX connected thereto may be arranged in the pixel area 11. The plurality of pixels PX may be arranged in various forms, such as a stripe arrangement, a PenTile arrangement, a diamond arrangement, and a mosaic arrangement, to display an image. Each pixel PX may include an organic light-emitting diode (OLED) as a display element (e.g., a light-emitting element), and the OLED may be connected to a pixel circuit. The pixel PX may emit, for example, red, green, blue, or white light through the OLED. Each pixel PX may be connected to at least one corresponding gate line among the plurality of gate lines GL and at least one corresponding data line among the plurality of data lines DL.

The pixel circuit may include a plurality of transistors and at least one capacitor. In some embodiments, the plurality of transistors included in the pixel circuit may be silicon thin-film transistors. In some other embodiments, the plurality of transistors included in the pixel circuit may be oxide thin-film transistors. In still some other embodiments, one or more of the plurality of transistors included in the pixel circuit may be oxide thin-film transistors, and one or more of the plurality of transistors included in the pixel circuit may be silicon thin-film transistors.

The silicon thin-film transistor may be a low-temperature polycrystalline silicon (LTPS) thin-film transistor in which a semiconductor layer includes amorphous silicon, polysilicon, and/or the like. The oxide thin-film transistor may be a low-temperature polycrystalline oxide (LTPO) thin-film transistor in which a semiconductor layer includes oxide. However, these are examples, and the silicon thin-film transistor and the oxide thin-film transistor are not limited thereto.

Each of the gate lines GL may extend in the x direction (e.g., a row direction) and may be connected to pixels PX located in the same row. The gate line GL may be configured to transmit a gate signal to the pixels PX of the same row. Each of the data lines DL may extend in the y direction (e.g., a column direction) and may be connected to pixels PX located in the same column. Each data line DL may be configured to transmit a data signal to each of the pixels PX of the same column in synchronization with the gate signal.

In some embodiments, the peripheral area PA (see, e.g., FIG. 1) may be a non-display area in which pixels PX are not arranged. Various conductive lines configured to transmit an electric signal which will be applied to the display area DA (see, e.g., FIG. 1), outer circuits electrically connected to pixel circuits, and pads on which a printed circuit board or a driver integrated circuit (IC) chip is attached may be in the peripheral area PA (see, e.g., FIG. 1). For example, the gate driving circuit 13, the data driving circuit 15, the power supply circuit 17, and the controller 19 may be provided in the peripheral area PA (see, e.g., FIG. 1).

The gate driving circuit 13 may be connected to the plurality of gate lines GL and may be configured to generate a gate signal GS in response to a driving control signal GCS from the controller 19 and sequentially supply the gate signal GS to the gate lines GL. The gate line GL may be connected to a gate of a transistor included in the pixel PX. The gate signal GS may be a gate control signal for controlling the turn-on and turn-off of a transistor (e.g., for turning on or turning off a transistor) having a gate connected to the gate line GL. The gate signal GS may be a square wave signal including a gate-on voltage at which the transistor may be turned on and a gate-off voltage at which the transistor may be turned off. In some embodiments, the gate-on voltage may be a high-level voltage or a low-level voltage.

Although FIG. 2 shows the pixel PX connected to one gate line GL, this is merely an example, and the pixel PX may be connected to two or more gate lines, and the gate driving circuit 13 may be configured to supply, to the corresponding gate lines, two or more gate signals that differ in timing at which the gate-on voltage is applied.

The data driving circuit 15 may be connected to the plurality of data lines DL and may be configured to supply a data signal DATA to the data lines DL in response to a driving control signal DCS from the controller 19. The data signal DATA supplied to the data line DL may be supplied to the pixel PX to which the gate signal GS is supplied. The data driving circuit 15 may be configured to convert input image data having a grayscale input from the controller 19 into the data signal DATA in the form of voltage or current.

The power supply circuit 17 may be configured to generate voltages for driving the pixel PX in response to a driving control signal PCS from the controller 19. The power supply circuit 17 may be configured to generate a driving voltage ELVDD and a common voltage ELVSS and supply the same to the pixel PX. The driving voltage ELVDD may be a high-level voltage which is provided to one terminal of a driving transistor connected to a first electrode (e.g., a pixel electrode or an anode) of the display element included in the pixel PX. The common voltage ELVSS may be a low-level voltage which is provided to a second electrode (e.g., an opposite electrode or a cathode) of the display element included in the pixel PX.

The controller 19 may generate the driving control signals GCS, DCS, and PCS based on signals input from the outside, and supply the same to the gate driving circuit 13, the data driving circuit 15, and the power supply circuit 17. The driving control signal GCS output to the gate driving circuit 13 may include a plurality of clock signals and a gate start signal. The driving control signal DCS output to the data driving circuit 15 may include a plurality of clock signals and a data start signal.

The display device 1 may include a display panel, and the display panel may include a substrate. The pixels PX may be arranged in the display area DA (see, e.g., FIG. 1) of the substrate. A portion or the entirety of the gate driving circuit 13 may be directly formed in the peripheral area PA (see, e.g., FIG. 2) of the substrate during a process of forming a transistor that constitutes the pixel circuit in the display area DA (see, e.g., FIG. 1) of the substrate. The data driving circuit 15, the power supply circuit 17, and the controller 19 may each be in the form of an individual IC chip or a single IC chip, and may be disposed on a flexible printed circuit board (FPCB) electrically connected to a pad arranged at one side of the substrate. In some other embodiments, the data driving circuit 15, the power supply circuit 17, and the controller 19 may be directly disposed on the substrate in a chip-on-glass (COG) or chip-on-plastic (COP) manner.

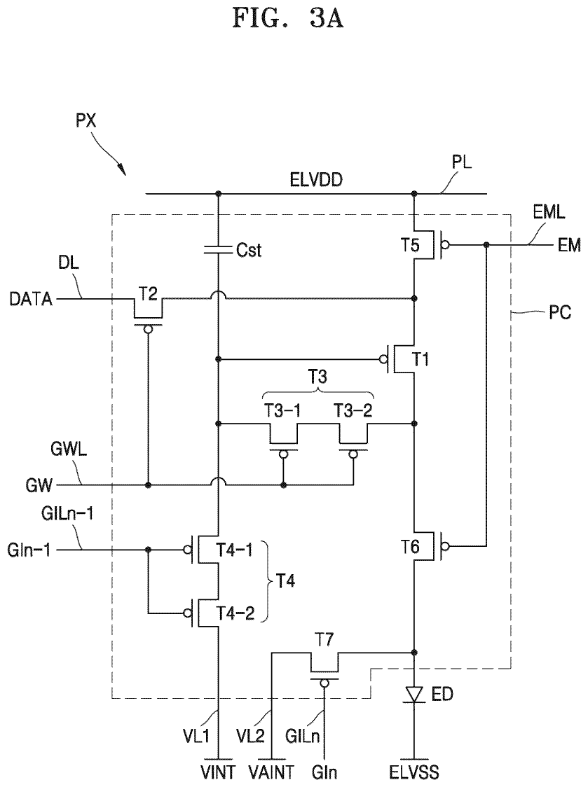

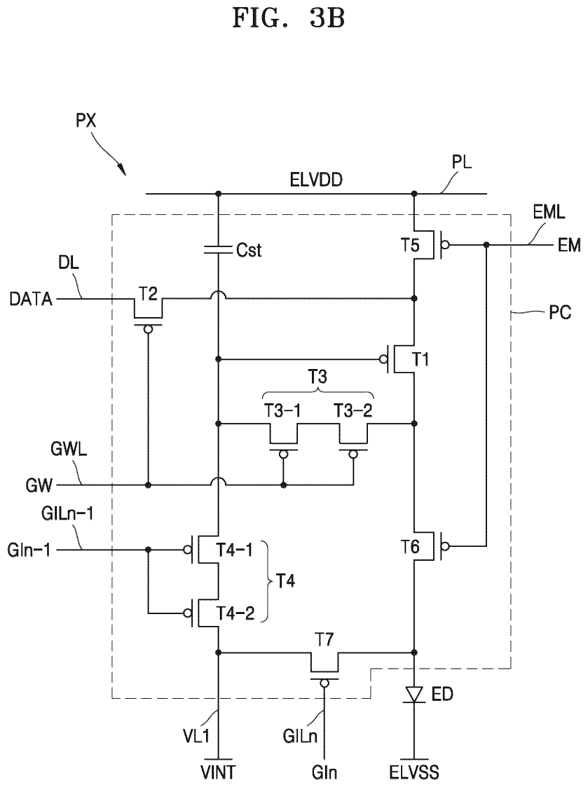

FIGS. 3A and 3B are equivalent circuit diagrams of one pixel included in a display device according to some embodiments of the present disclosure.

Referring to FIGS. 3A and 3B, a pixel circuit PC may include first to seventh transistors T1 to T7 and a storage capacitor Cst. According to a type (e.g., p-type or n-type) and/or an operating condition of a transistor, a first terminal of each of the first to seventh transistors T1 to T7 may be a source or a drain and a second terminal may be a terminal different from the first terminal. For example, when the first terminal is a source, the second terminal may be a drain. The first transistor T1 may be a driving transistor in which a magnitude of source-drain current is determined according to a gate-source voltage, and the second to seventh transistors T2 to T7 may be switching transistors that transmit signals.

The pixel circuit PC may be connected to a first gate line GWL transmitting a first gate signal GW, an (n−1)th second gate line GILn−1 transmitting an (n−1)th second gate signal GIn−1, an nth second gate line GIn transmitting an nth second gate signal GIn, an light emission control line EML transmitting an emission control signal EM, a data line DL transmitting a data signal DATA, a driving voltage line PL transmitting a driving voltage ELVDD, a first initialization voltage line VL1 transmitting a first initialization voltage VINT, and a second initialization voltage line VL2 transmitting a second initialization voltage VAINT.

The first transistor T1 may be connected electrically between the driving voltage line PL and a light-emitting diode ED. The first transistor T1 may include a first terminal electrically connected to the driving voltage line PL via the fifth transistor T5, a second terminal electrically connected to the light-emitting diode ED via the sixth transistor T6, and a gate electrode connected to the storage capacitor Cst. The first transistor T1 may be configured to receive the data signal DATA according to a switching operation of the second transistor T2 and may supply a driving current to the light-emitting diode ED. That is, the first transistor T1 may be defined as a driving transistor.

The second transistor T2 may be electrically connected between the data line DL and the first terminal of the first transistor T1. The second transistor T2 may include a gate electrode connected to the first gate line GWL, a first terminal connected to the data line DL, and a second terminal connected to the first terminal of the first transistor T1. The second terminal of the second transistor T2 may be connected to the first terminal of the transistor T1, and may be connected to the driving voltage line PL via the fifth transistor T5. The second transistor T2 may be turned on according to (e.g., in response to) the first gate signal GW received through the first gate line GWL to perform a switching operation for transmitting the data signal DATA transmitted to the data line DL to the first transistor T1. That is, the second transistor T2 may be defined as a switching transistor.

The third transistor T3 may be electrically connected between the gate electrode of the first transistor T1 and the second terminal of the first transistor T1. The third transistor T3 may include a first terminal connected to the second terminal of the first transistor T1, a second terminal connected to the gate electrode of the first transistor T1, and a gate electrode connected to the first gate line GWL. The third transistor T3 may be turned on according to (e.g., in response to) the first gate signal GW transmitted through the first gate line GWL to connect the gate electrode and the second terminal of the first transistor T1 to each other to diode-connect the first transistor T1. That is, the third transistor T3 may be defined as a compensation transistor.

The third transistor T3 may include a first sub-transistor T3-1 and a second sub-transistor T3-2. The first sub-transistor T3-1 and the second sub-transistor T3-2 may be connected in series between the gate electrode of the first transistor T1 and the second terminal of the first transistor T1.

The first sub-transistor T3-1 may include a first terminal connected to a second terminal of the second sub-transistor T3-2, a second terminal connected to the gate electrode of the first transistor T1, and a gate electrode connected to the first gate line GWL. The second terminal of the first sub-transistor T3-1 may correspond to the second terminal of the third transistor T3. The second sub-transistor T3-2 may include a first terminal connected to the second terminal of the first transistor T1, a second terminal connected to the first terminal of the first sub-transistor T3-1, and a gate electrode connected to the first gate line GWL. The first terminal of the second sub-transistor T3-2 may correspond to the first terminal of the third transistor T3.

The fourth transistor T4 may be electrically connected between the gate electrode of the first transistor T1 and the first initialization voltage line VL1. The fourth transistor T4 may include a first terminal connected to the gate electrode of the first transistor T1, a second terminal connected to the first initialization voltage line VL1 to which the first initialization voltage VINT is transmitted, and a gate electrode connected to the (n−1)th second gate line GILn−1. The first terminal of the fourth transistor T4 may be connected to the gate electrode of the first transistor T1, the second terminal of the third transistor T3, and the storage capacitor Cst. The fourth transistor T4 may be turned on according to (e.g., in response to) the (n−1)th second gate signal GIn−1 transmitted through the (n−1)th second gate line GILn−1 to transmit the first initialization voltage VINT to the gate electrode of the first transistor T1 to initialize the voltage of the gate electrode of the first transistor T1. That is, the fourth transistor T4 may be defined as a first initialization transistor.

The fourth transistor T4 may include a third sub-transistor T4-1 and a fourth sub-transistor T4-2. The third sub-transistor T4-1 and the fourth sub-transistor T4-2 may be connected in series between the gate electrode of the first transistor T1 and the first initialization voltage line VL1.

The third sub-transistor T4-1 may include a first terminal connected to the gate electrode of the first transistor T1, a second terminal connected to the fourth sub-transistor T4-2, and a gate electrode connected to the (n−1)th second gate line GILn−1. The first terminal of the third sub-transistor T4-1 may correspond to the first terminal of the fourth transistor T4. The fourth sub-transistor T4-2 may include a first terminal connected to the third sub-transistor T4-1, a second terminal connected to the first initialization voltage line VL1, and a gate electrode connected to the (n−1)th second gate line GILn−1. The second terminal of the fourth sub-transistor T4-2 may correspond to the second terminal of the fourth transistor T4.

The fifth transistor T5 may be electrically connected between the driving voltage line PL and the first transistor T1. The fifth transistor T5 may include a first terminal connected to the driving voltage line PL, a second terminal connected to the first terminal of the first transistor T1, and a gate electrode connected to the light emission control line EML.

The sixth transistor T6 may be electrically connected between the first transistor T1 and the light-emitting diode ED. The sixth transistor T6 may include a first terminal connected to the first transistor T1, a second terminal connected to the pixel electrode of the light-emitting diode ED, and a gate electrode connected to the light emission control line EML.

The fifth transistor T5 and the sixth transistor T6 may be concurrently (e.g., simultaneously or substantially simultaneously) turned on according to (e.g., in response to) the emission control signal EM transmitted through the light emission control line EML, so that the driving voltage ELVDD is transmitted to the light-emitting diode ED, and a driving current flows through the light-emitting diode ED. That is, the fifth transistor T5 may be defined as a driving control transistor, and the sixth transistor T6 may be defined as an emission control transistor.

Referring to FIG. 3A, in some embodiments, the seventh transistor T7 may be connected between the second initialization voltage line VL2 and the light-emitting diode ED. The seventh transistor T7 may include a first terminal connected to the second initialization voltage line VL2 transmitting the second initialization voltage VAINT, a second terminal connected to the light-emitting diode ED, and a gate electrode connected to the nth second gate line GILn. The second terminal of the seventh transistor T7 may be connected to the sixth transistor T6 and the light-emitting diode ED. The seventh transistor T7 may be turned on according to (e.g., in response to) the nth second gate signal GIn transmitted through the nth second gate line GILn to initialize the pixel electrode of the light-emitting diode ED. That is, the seventh transistor T7 may be defined as a second initialization transistor.

In some other embodiments, referring to FIG. 3B, the seventh transistor T7 may be electrically connected between the fourth transistor T4 and the sixth transistor T6. The seventh transistor T7 may include a first terminal connected to the fourth transistor T4, a second terminal connected to the sixth transistor T6, and a gate electrode connected to the nth second gate line GILn. In this case, the first terminal of the seventh transistor T7 may be electrically connected to the first initialization voltage line VL1 together with the fourth transistor T4, and the second terminal of the seventh transistor T7 may be electrically connected to the light emitting diode ED together with the sixth transistor T6.

In FIGS. 3A and 3B, the fourth transistor T4 and the seventh transistor T7 are connected to the (n−1)th second gate line GILn−1 and the nth second gate line GILn, respectively, but the disclosure is not limited thereto. In some other embodiments, both the fourth transistor T4 and the seventh transistor T7 may be connected to the (n−1)th second gate line GILn−1 and may be driven according to (e.g., in response to) the (n−1)th second gate signal GIn−1.

The storage capacitor Cst may include a first electrode and a second electrode. The first electrode of the storage capacitor Cst may be connected to the gate electrode of the first transistor T1, the second terminal of the third transistor T3, and the first terminal of the fourth transistor T4. The second electrode of the storage capacitor Cst may be connected to the driving voltage line PL.

The light-emitting diode ED may include the pixel electrode (e.g., an anode) and the opposite electrode (e.g., a cathode) facing the pixel electrode. The opposite electrode of the light-emitting diode ED may receive the common voltage ELVSS. The light-emitting diode ED may receive the driving current from the first transistor T1 and may emit light to display an image.

The pixel circuit PC is not limited to the number of transistors and storage capacitors and the circuit design described with reference to FIGS. 3A and 3B, and the number and the circuit design may be variously changed. Pixel circuits PC driving the pixels PX in the display area DA (see, e.g., FIG. 1) may be provided identically or differently.

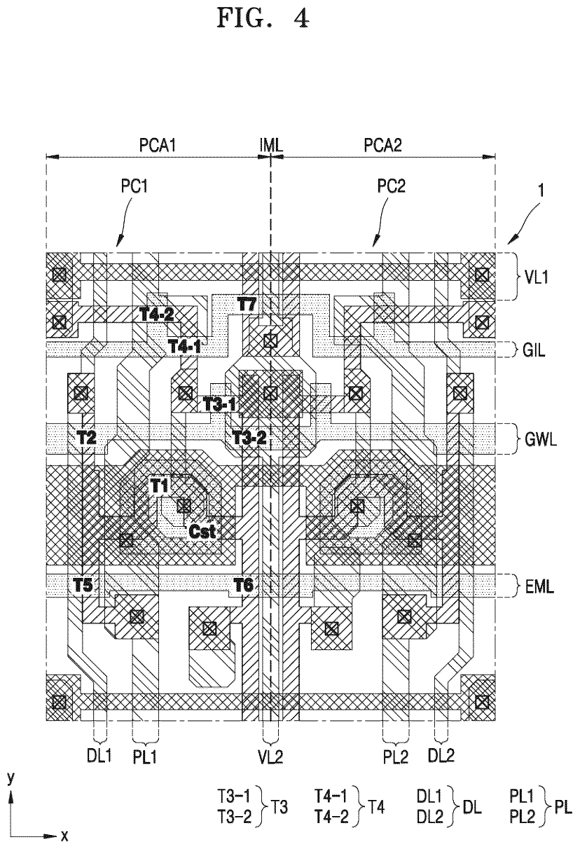

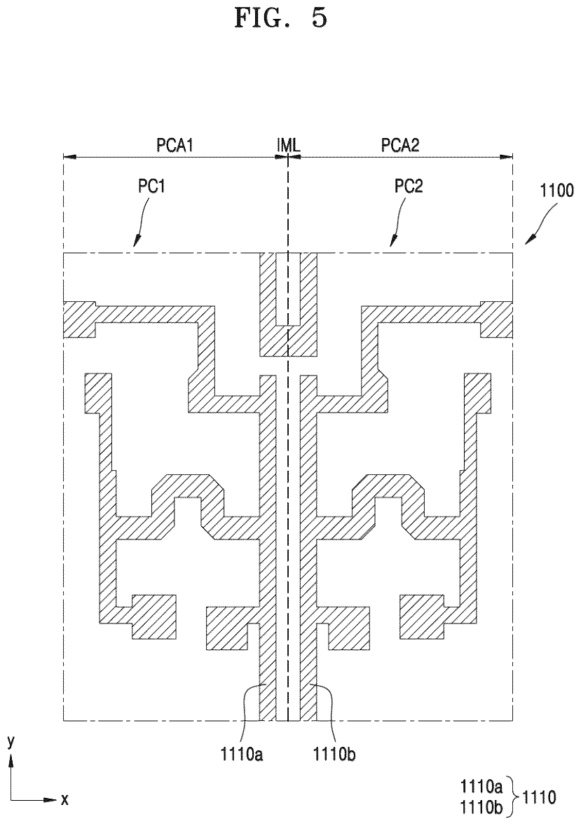

FIG. 4 is a layout view schematically illustrating a portion of a display device according to some embodiments of the present disclosure. FIGS. 5 to 9 are layout views each schematically illustrating a portion of the display device of FIG. 4 for each layer according to some embodiments of the present disclosure.

First, referring to FIG. 4, the display device 1 may include a first pixel circuit area PCA1 in which a first pixel circuit PC1 is disposed, and a second pixel circuit area PCA2 in which a second pixel circuit PC2 is disposed. The first pixel circuit area PCA1 and the second pixel circuit area PCA2 may be disposed side by side in the first direction (e.g., the x direction). That is, the first pixel circuit PC1 and the second pixel circuit PC2 may be pixel circuits disposed in the same pixel circuit row. The first pixel circuit PC1 and the second pixel circuit PC2 may constitute a single pixel circuit unit. A unit area including the first pixel circuit area PCA1 and the second pixel circuit area PCA2 may be repeatedly arranged in the first direction (e.g., the x direction) and the second direction (e.g., the y direction).

Each of the first pixel circuit PC1 and the second pixel circuit PC2 may include the first to seventh transistors T1 to T7 and the storage capacitor Cst. Each of the first pixel circuit PC1 and the second pixel circuit PC2 may further include conductive patterns for connecting the first to seventh transistors T1 to T7 and the storage capacitor Cst to the gate lines, voltage lines, data lines, and pixel electrodes.

Each of the first pixel circuit PC1 and the second pixel circuit PC2 may include substantially the same or similar components unless otherwise described. Although components of the first pixel circuit PC1 are mainly described for convenience of explanation, components corresponding to the components of the first pixel circuit PC1 may be included in the second pixel circuit PC2.

The first pixel circuit PC1 and the second pixel circuit PC2 may have a flip structure (e.g., a mirroring or mirror image structure). For example, the first pixel circuit PC1 and the second pixel circuit PC2 may be substantially line-symmetrical to each other with respect to an imaginary straight line IML extending in the second direction (e.g., the y direction) along a boundary between the first pixel circuit PC1 and the second pixel circuit PC2. For example, in the first pixel circuit PC1, the second transistor T2 may be located on a left side (−x direction) with respect to the first transistor T1, and in the second pixel circuit PC2, the second transistor T2 may be located on a right side (+x direction) with respect to the first transistor T1.

In some embodiments, the third transistor T3 of the first pixel circuit PC1 may be line-symmetrical to the third transistor T3 of the second pixel circuit PC2, with respect to the imaginary straight line IML extending in the second direction (e.g., the y direction). Likewise, the fourth transistor T4 of the first pixel circuit PC1 may be line-symmetrical to the fourth transistor T4 of the second pixel circuit PC2, with respect to the imaginary straight line IML extending in the second direction (e.g., the y direction). The flip structure as described above will be described in detail with reference to FIGS. 5 to 9.

The first pixel circuit PC1 and the second pixel circuit PC2 may be connected to the gate lines, the data lines, and the voltage lines. The gate lines may include the first gate line GWL, the second gate line GIL, and the light emission control line EML. The first gate line GWL, the second gate line GIL, and the light emission control line EML may extend in the first direction (e.g., the x direction).

The voltage lines may include the first initialization voltage line VL1, the second initialization voltage line VL2, and the driving voltage line PL. The first initialization voltage line VL1 may extend along the first direction (e.g., the x direction), and the second initialization voltage line VL2 and the driving voltage line PL may extend along the second direction (e.g., the y direction). The driving voltage line PL may include a first driving voltage line PL1 and a second driving voltage line PL2. The first driving voltage line PL1 may be connected to the first pixel circuit PC1, and the second driving voltage line PL2 may be connected to the second pixel circuit PC2.

In some embodiments, the first pixel circuit PC1 and the second pixel circuit PC2 may share one second initialization voltage line VL2. For example, the second initialization voltage line VL2 extending in the second direction (e.g., the y direction) may be disposed on the boundary between the first pixel circuit area PCA1 and the second pixel circuit area PCA2. Accordingly, a partial area of the second initialization voltage line VL2 may be disposed in the first pixel circuit area PCA1 to be connected to the first pixel circuit PC1, and another area of the second initialization voltage line VL2 may be disposed in the second pixel circuit area PCA2 to be connected to the second pixel circuit PC2.

The data lines DL may include a first data line DL1 and a second data line DL2. The data lines DL may be disposed to extend in the second direction (e.g., the y direction). The first data line DL1 may be disposed in the first pixel circuit area PCA1 to be connected to the first pixel circuit PC1, and the second data line DL2 may be disposed in the second pixel circuit area PCA2 to be connected to the second pixel circuit PC2.

Referring to FIG. 5, a first semiconductor layer 1100 may be disposed on the substrate. The first semiconductor layer 1100 may include a silicon-based semiconductor material, for example, amorphous silicon or polycrystalline silicon.

The first semiconductor layer 1100 may include a first semiconductor pattern 1110. For convenience of explanation, the first semiconductor pattern 1110 disposed in the first pixel circuit area PCA1 may be referred to as a first-1 semiconductor pattern 1110a, and the first semiconductor pattern 1110 disposed in the second pixel circuit area PCA2 may be referred to as a first-2 semiconductor pattern 1110b.

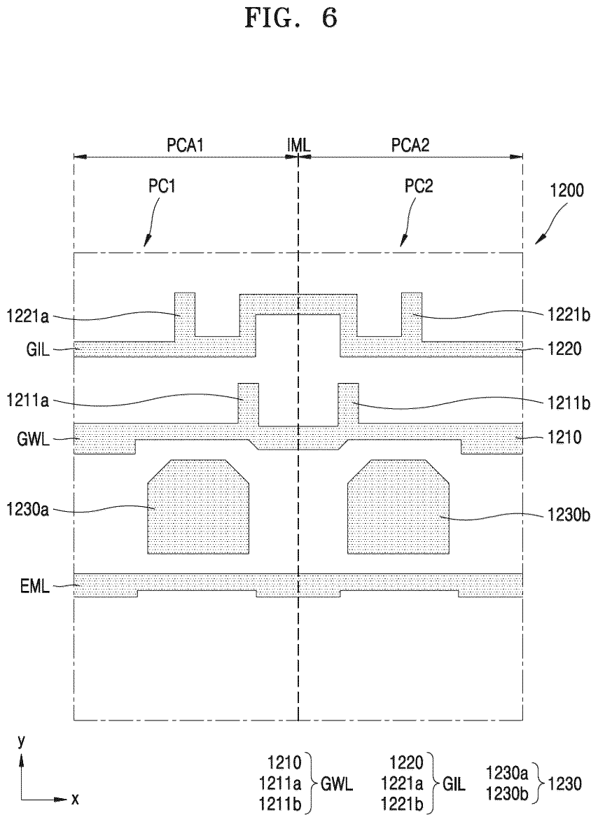

Referring to FIG. 6, a first conductive layer 1200 may be disposed on the first semiconductor layer 1100. The first conductive layer 1200 may include a conductive material, such as molybdenum (Mo), aluminum (Al), copper (Cu), titanium (Ti), or the like, and may be a multilayer or a single layer including the above material. The first conductive layer 1200 may include the first gate line GWL, the second gate line GIL, the light emission control line EML, and a first conductive pattern 1230.

The first conductive pattern 1230 may have an isolated shape (island type) in a plan view. The first conductive pattern 1230 may include a first-1 conductive pattern 1230a disposed in the first pixel circuit area PCA1 and a first-2 conductive pattern 1230b disposed in the second pixel circuit area PCA2. The first gate line GWL, the second gate line GIL, and the light emission control line EML may extend in the first direction (e.g., the x direction) to pass through the first pixel circuit area PCA1 and the second pixel circuit area PCA2. The first gate line GWL may transmit the first gate signal GW (see, e.g., FIG. 3A) to the first pixel circuit PC1 and the second pixel circuit PC2 disposed in the same pixel circuit row. The second gate line GIL may transmit the second gate signals GIn and GIn−1 (see, e.g., FIG. 3A) to the first pixel circuit PC1 and the second pixel circuit PC2 disposed in the same pixel circuit row.

In some embodiments, the first gate line GWL may include a first trunk portion 1210 extending in the first direction (e.g., the x direction), a first branch portion 1211a branched from the first trunk portion 1210 in the first pixel circuit area PCA1 and extending in the second direction (e.g., the y direction), and a second branch portion 1211b branched from the first trunk portion 1210 in the second pixel circuit area PCA2 and extending in the second direction (e.g., the y direction). Likewise, the second gate line GIL may include a second trunk portion 1220 extending in the first direction (e.g., the x direction), a third branch portion 1221a branched from the second trunk portion 1220 in the first pixel circuit area PCA1 and extending in the second direction (e.g., the y direction), and a fourth branch portion 1221b branched from the second trunk portion 1220 in the second pixel circuit area PCA2 and extending in the second direction (e.g., the y direction).

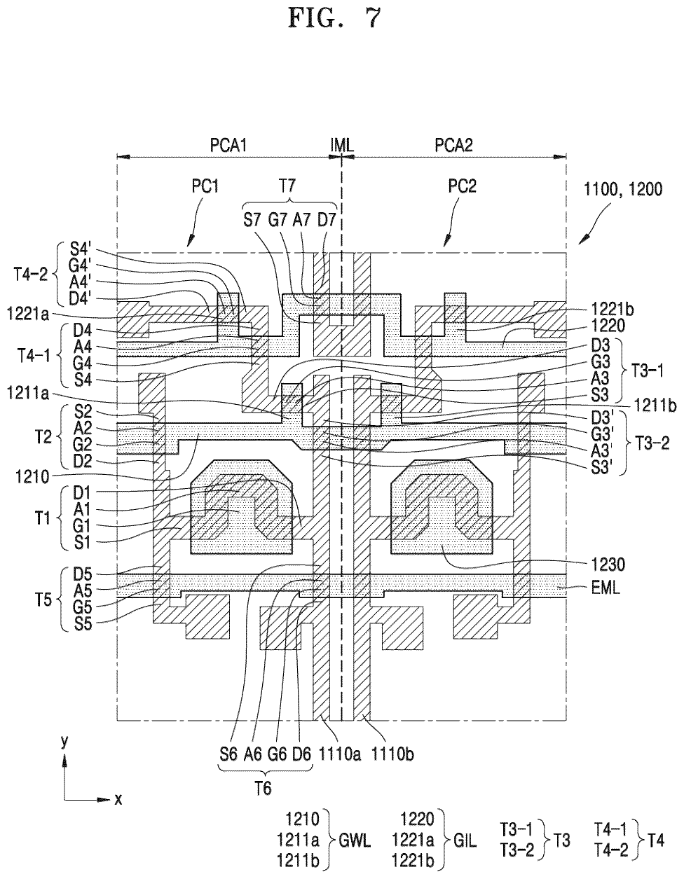

FIG. 7 shows the first semiconductor layer 1100 and the first conductive layer 1200 overlapping each other for convenience of explanation. Referring to FIG. 7, each of the first-1 semiconductor pattern 1110a and the first-2 semiconductor pattern 1110b may include a first channel region A1 of the first transistor T1, a second channel region A2 of the second transistor T2, a third-1 channel region A3 of the first sub-transistor T3-1, a third-2 channel region A3′ of the second sub-transistor T3-2, a fourth-1 channel region A4 of the third sub-transistor T4-1, a fourth-2 channel region A4′ of the fourth sub-transistor T4-2, a fifth channel region A5 of the fifth transistor T5, a sixth channel region A6 of the sixth transistor T6, and a seventh channel region A7 of the seventh transistor T7. A source region and a drain region may be disposed at both sides of each of the first to seventh channel regions A1 to A7. The first to seventh channel regions A1 to A7 of the first pixel circuit PC1 may be integrally provided to constitute a first-1 semiconductor pattern 1110a, and the first to seventh channel regions A1 to A7 of the second pixel circuit PC2 may be integrally provided to constitute a first-2 semiconductor pattern 1110b.

The first channel region A1 of the first transistor T1 may overlap the first conductive pattern 1230. In some embodiments, the first channel region A1 of the first-1 semiconductor pattern 1110a and the first channel region A1 of the first-2 semiconductor pattern 1110b may have a curved shape. However, the disclosure is not limited thereto, and in some other embodiments, the first channel region A1 of the first-1 semiconductor pattern 1110a and the first channel region A1 of the first-2 semiconductor pattern 1110b may have a linear shape. The first conductive pattern 1230 may be a first gate electrode G1 of the first transistor T1. A first source region S1 and a first drain region D1 may be disposed at both sides of the first channel region A1 of the first transistor T1.

The second channel region A2 of the second transistor T2 may overlap a portion of the first gate line GWL. The portion of the first gate line GWL overlapping the second channel region A2 may be a second gate electrode G2 of the second transistor T2. A second source region S2 and a second drain region D2 may be disposed at both sides of the second channel region A2 of the second transistor T2 respectively. The first source region S1 of the first transistor T1 may be disposed between the first channel region A1 of the first transistor T1 and the second channel region A2 of the second transistor T2.

The third transistor T3 may include the first sub-transistor T3-1 and the second sub-transistor T3-2. The third-1 channel region A3 of the first sub-transistor T3-1 and the third-2 channel region A3′ of the second sub-transistor T3-2 may overlap a portion of the first gate line GWL. For example, a portion of the first branch portion 1211a of the first gate line GWL, which overlaps the third-1 channel area A3, may be a third-1 gate electrode G3 of the first sub-transistor T3-1. A portion of the first trunk portion 1210 of the first gate line GWL overlapping the third-2 channel region A3′ may be a third-2 gate electrode G3′ of the second sub-transistor T3-2. A third-1 source region S3 and a third-1 drain region D3 may be disposed on both sides of the third-1 channel region A3 of the first sub-transistor T3-1 respectively. A third-2 source region S3′ and a third-2 drain region D3′ may be disposed on both sides of the third-2 channel region A3′ of the second sub-transistor T3-2 respectively.

In some embodiments, the third transistor T3 of the first pixel circuit PC1 and the third transistor T3 of the second pixel circuit PC2 may have the flip structure. That is, the third transistor T3 of the first pixel circuit PC1 and the third transistor T3 of the second pixel circuit PC2 may be line-symmetrical to each other with respect to the imaginary straight line IML disposed at the boundary between the first pixel circuit area PCA1 and the second pixel circuit area PCA2. For example, the first sub-transistor T3-1 of the first pixel circuit PC1 may be line-symmetrical to the first sub-transistor T3-1 of the second pixel circuit PC2, and the second sub-transistor T3-2 of the first pixel circuit PC1 may be line-symmetrical to the second sub-transistor T3-2 of the second pixel circuit PC2. For example, a distance from the boundary between the first pixel circuit area PCA1 and the second pixel circuit area PCA2 to the first branch portion 1211a may be the same or substantially the same as a distance from the boundary between the first pixel circuit area PCA1 and the second pixel circuit area PCA2 to the second branch portion 1211b.

The third transistor T3 may be disposed closer to the boundary between the first pixel circuit area PCA1 and the second pixel circuit area PCA2 than the second transistor T2 with respect to the first direction (e.g., the x direction). For example, the third transistor T3 of the first pixel circuit PC1 may be disposed on the right side of the second transistor T2 in the first direction (e.g., the x direction), and the third transistor T3 of the second pixel circuit PC2 may be disposed on the left side of the second transistor T2 in the first direction (e.g., the x direction).

The fourth transistor T4 may include the third sub-transistor T4-1 and the fourth sub-transistor T4-2. The fourth-1 channel region A4 of the third sub-transistor T4-1 and the fourth-2 channel region A4′ of the fourth sub-transistor T4-2 may overlap a portion of the second gate line GIL. For example, a portion of the second trunk portion 1220 of the second gate line GIL, which overlaps the fourth-1 channel area A4, may be a fourth-1 gate electrode G4 of the third sub-transistor T4-1. A portion of the third branch portion 1221a of the second gate line GIL overlapping the fourth-2 channel region A4′ may be a fourth-2 gate electrode G4′ of the fourth sub-transistor T4-2. A fourth-1 source region S4 and a fourth-1 drain region D4 may be disposed on both sides of the fourth-1 channel region A4 of the third sub-transistor T4-1 respectively. A fourth-2 source region S4′ and a fourth-2 drain region D4′ may be disposed at both sides of the fourth-2 channel region A4′ of the fourth sub-transistor T4-2 respectively.

In some embodiments, the fourth transistor T4 of the first pixel circuit PC1 and the fourth transistor T4 of the second pixel circuit PC2 may have the flip structure. That is, the fourth transistor T4 of the first pixel circuit PC1 and the fourth transistor T4 of the second pixel circuit PC2 may be line-symmetrical to each other with respect to the imaginary straight line IML disposed at the boundary between the first pixel circuit area PCA1 and the second pixel circuit area PCA2. For example, the third sub-transistor T4-1 of the first pixel circuit PC1 may be line-symmetrical to the third sub-transistor T4-1 of the second pixel circuit PC2, and the fourth sub-transistor T4-2 of the first pixel circuit PC1 may be line-symmetrical to the fourth sub-transistor T4-2 of the second pixel circuit PC2. For example, a distance from the boundary between the first pixel circuit area PCA1 and the second pixel circuit area PCA2 to the third branch portion 1221a may be the same or substantially the same as a distance from the boundary between the first pixel circuit area PCA1 and the second pixel circuit area PCA2 to the fourth branch portion 1221b.

The fifth channel region A5 of the fifth transistor T5 and the sixth channel region A6 of the sixth transistor T6 may overlap a portion of the light emission control line EML. The portion of the light emission control line EML overlapping the fifth channel region A5 may be a fifth gate electrode G5 of the fifth transistor T5, and the portion of the light emission control line EML overlapping the sixth channel region A6 may be a sixth gate electrode G6 of the sixth transistor T6. A fifth source region S5 and a fifth drain region D5 may be disposed at both sides of the fifth channel region A5 of the fifth transistor T5 respectively. A sixth source region S6 and a sixth drain region D6 may be disposed at both sides of the sixth channel region A6 of the sixth transistor T6 respectively.

The sixth transistor T6 may be disposed closer to the boundary between the first pixel circuit area PCA1 and the second pixel circuit area PCA2 than the fifth transistor T5 with respect to the first direction (e.g., the x direction). For example, the sixth transistor T6 of the first pixel circuit PC1 may be disposed on the right side of the fifth transistor T5 in the first direction (e.g., the x direction), and the sixth transistor T6 of the second pixel circuit PC2 may be disposed on the left side of the fifth transistor T5 in the first direction (e.g., the x direction).

The seventh channel region A7 of the seventh transistor T7 may overlap a portion of the second gate line GIL. A portion of the second gate line GIL overlapping the seventh channel region A7 may be a seventh gate electrode G7 of the seventh transistor T7. For example, the seventh gate electrode G7 may be a partial area of the second trunk portion 1220. A seventh source region S7 and a seventh drain region D7 may be disposed on both sides of the seventh channel region A7 of the seventh transistor T7 respectively.

The seventh transistor T7 may be disposed closer to the boundary between the first pixel circuit area PCA1 and the second pixel circuit area PCA2 than the fourth transistor T4 with respect to the first direction (e.g., the x direction). For example, the seventh transistor T7 of the first pixel circuit PC1 may be disposed on the right side of the fourth transistor T4 in the first direction (e.g., the x direction), and the seventh transistor T7 of the second pixel circuit PC2 may be disposed on the left side of the fourth transistor T4 in the first direction (e.g., the x direction).

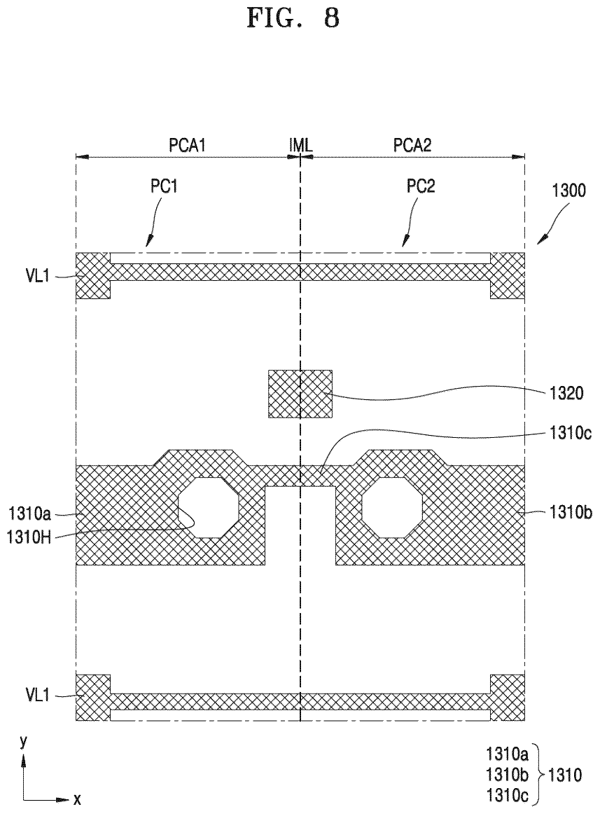

Referring to FIG. 8, a second conductive layer 1300 may be disposed on the first conductive layer 1200. The second conductive layer 1300 may include a conductive material, such as molybdenum (Mo), aluminum (Al), copper (Cu), titanium (Ti), or the like, and may be a multilayer or a single layer including the above material. The second conductive layer 1300 may include the first initialization voltage line VL1, a second conductive pattern 1310, and a third conductive pattern 1320.

The first initialization voltage line VL1 may extend in the first direction (e.g., the x direction) and pass through the first pixel circuit area PCA1 and the second pixel circuit area PCA2. The first initialization voltage line VL1 may transmit the first initialization voltage VINT (see, e.g., FIG. 3A) to the first pixel circuit PC1 and the second pixel circuit PC2 disposed in the same pixel circuit row. The first initialization voltage line VL1 may also be referred to as a horizontal initialization voltage line.

The second conductive pattern 1310 may extend in the first direction (e.g., the x direction) and pass through the first pixel circuit area PCA1 and the second pixel circuit area PCA2. The second conductive pattern 1310 may include a first body portion 1310a disposed in the first pixel circuit area PCA1, a second body portion 1310b disposed in the second pixel circuit area PCA2, and a horizontal connection portion 1310c connecting the first body portion 1310a and the second body portion 1310b.

The first body portion 1310a and the second body portion 1310b may overlap the first conductive pattern 1230 in a plan view to form the storage capacitor Cst (see, e.g., FIG. 4). For example, the first conductive pattern 1230 may function as a first electrode of the storage capacitor Cst (see, e.g., FIG. 4), and the first body portion 1310a may function as a second electrode of the storage capacitor Cst (see, e.g., FIG. 4). Likewise, the second body portion 1310b may also function as the second electrode of the storage capacitor Cst (see, e.g., FIG. 4). Each of the first body portion 1310a and the second body portion 1310b may define a first hole 1310H. exposing a portion of the first conductive pattern 1230.

The third conductive pattern 1320 may have an isolated shape in a plan view. The third conductive pattern 1320 may be disposed on the boundary between the first pixel circuit area PCA1 and the second pixel circuit area PCA2. For example, the third conductive pattern 1320 may be shared by the first pixel circuit PC1 and the second pixel circuit PC2. The third conductive pattern 1320 may overlap a common region of the first semiconductor layer 1100 disposed between the third-1 source region S3 of the first sub-transistor T3-1 and the third-2 drain region D3′ of the second sub-transistor T3-2 (see, e.g., FIG. 7), and may form a stabilization capacitor. The stabilization capacitor may maintain relatively constant voltage levels of the second terminal of the first sub-transistor T3-1 and the first terminal of the second sub-transistor T3-2 (see, e.g., FIG. 7). Accordingly, the stabilization capacitor may reduce the leakage current of the third transistor T3 and improve the performance of the third transistor T3 (see, e.g., FIG. 7).

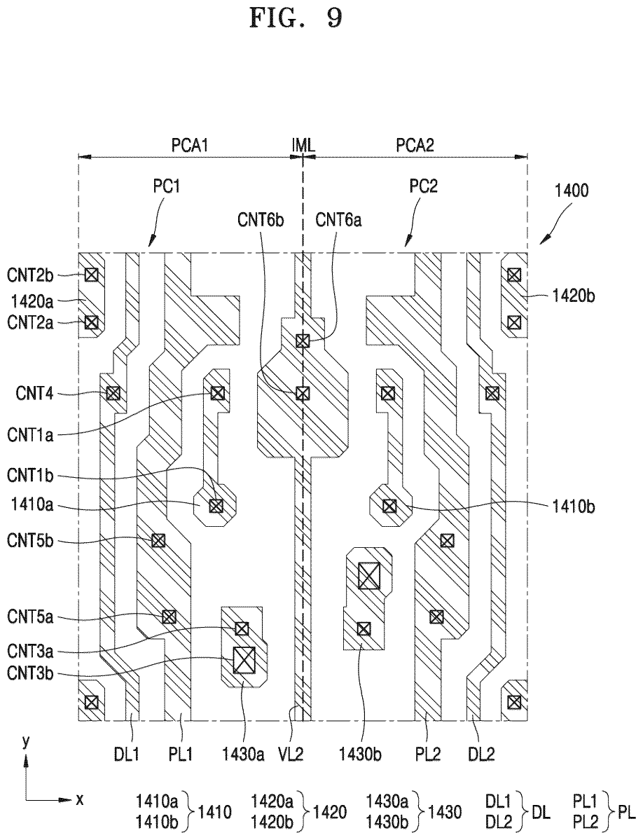

Referring to FIG. 9, a third conductive layer 1400 may be disposed on the second conductive layer 1300. The third conductive layer 1400 may include a conductive material, such as molybdenum (Mo), aluminum (Al), copper (Cu), or titanium (Ti), or the like, and may be a multilayer or a single layer including the above material. The third conductive layer 1400 may include the data line DL, the driving voltage line PL, the second initialization voltage line VL2, a fourth conductive pattern 1410, a fifth conductive pattern 1420, and a sixth conductive pattern 1430. The fourth conductive pattern 1410, the fifth conductive pattern 1420, and the sixth conductive pattern 1430 may have an isolated shape in a plan view (e.g., may be spaced apart from each other).

The fourth conductive pattern 1410 may be a connection electrode connecting the first gate electrode G1 of the first transistor T1, the third-1 drain region D3 of the first sub-transistor T3-1, and the fourth-1 source region S4 of the third sub-transistor T4-1. The fourth conductive pattern 1410 may be connected to the first semiconductor pattern 1110 through a first-1 contact hole CNT1a, and may be connected to the first conductive pattern 1230 through a first-2 contact hole CNT1b. The fourth conductive pattern 1410 may include a fourth-1 conductive pattern 1410a disposed in the first pixel circuit area PCA1, and a fourth-2 conductive pattern 1410b disposed in the second pixel circuit area PCA2. The fourth-1conductive pattern 1410a and the fourth-2 conductive pattern 1410b may be line-symmetric with respect to the boundary between the first pixel circuit area PCA1 and the second pixel circuit area PCA2.

The fifth conductive pattern 1420 may be a connection electrode connecting the fourth-2 drain region D4′ of the fourth sub-transistor T4-2 to the first initialization voltage line VL1. The fifth conductive pattern 1420 may be connected to the first semiconductor pattern 1110 through a second-1 contact hole CNT2a, and may be connected to the first initialization voltage line VL1 through a second-2 contact hole CNT2b. The fifth conductive pattern 1420 may include a fifth-1 conductive pattern 1420a disposed in the first pixel circuit area PCA1 and a fifth-2 conductive pattern 1420b disposed in the second pixel circuit area PCA2. The fifth-1 conductive pattern 1420a and the fifth-2 conductive pattern 1420b may be line-symmetrical with respect to the boundary between the first pixel circuit area PCA1 and the second pixel circuit area PCA2.

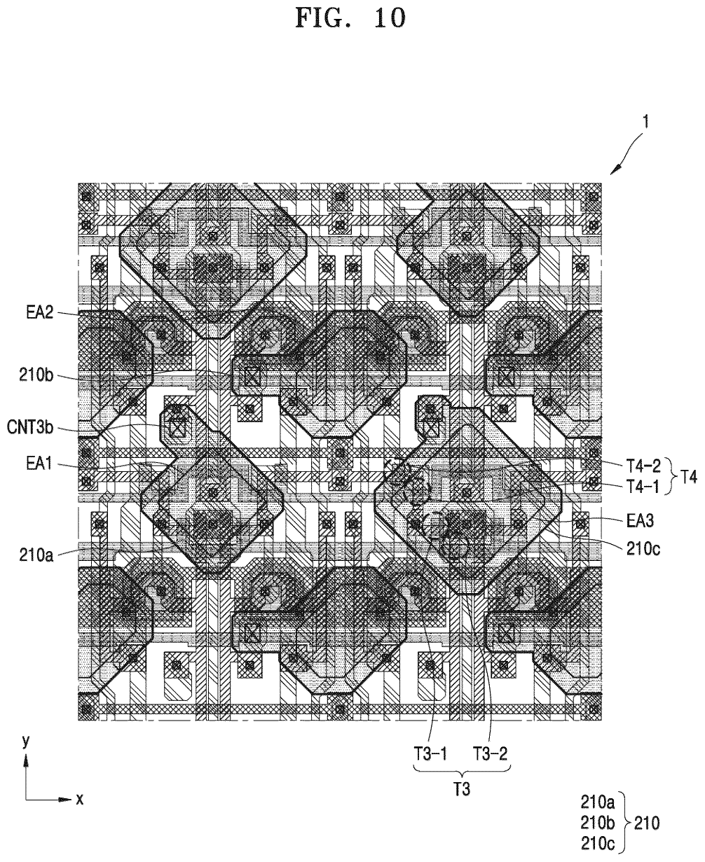

The sixth conductive pattern 1430 may be a connection electrode connecting the sixth drain region D6 of the sixth transistor T6, the seventh drain region D7 of the seventh transistor T7, and the pixel electrode 210 (see, e.g., FIG. 10). The sixth conductive pattern 1430 may include a sixth-1 conductive pattern 1430a disposed in the first pixel circuit area PCA1, and a sixth-2 conductive pattern 1430b disposed in the second pixel circuit area PCA2. The sixth conductive pattern 1430 may be connected to the first semiconductor pattern 1110 through a third-1 contact hole CNT3a, and may be connected to the pixel electrode 210 (see, e.g., FIG. 10) through a third-2 contact hole CNT3b.

The data line DL may extend in the second direction (e.g., the y direction). The data line DL may include a first data line DL1 disposed in the first pixel circuit area PCA1, and a second data line DL2 disposed in the second pixel circuit area PCA2. The data line DL may be connected to the second source region S2 of the second transistor T2 through a fourth contact hole CNT4.

The driving voltage line PL may extend in the second direction (e.g., the y direction). The driving voltage line PL may include a first driving voltage line PL1 disposed in the first pixel circuit area PCA1 and a second driving voltage line PL2 disposed in the second pixel circuit area PCA2. The driving voltage line PL may be connected to the fifth source region S5 of the fifth transistor T5 through the fifth-1 contact hole CNT5a, and may be connected to the first conductive pattern 1230 through the fifth-2 contact hole CNT5b. For example, the first conductive pattern 1230 may serve as the first electrode of the storage capacitor Cst (see, e.g., FIG. 3A).

In some embodiments, the driving voltage line PL may be disposed relatively close to the boundary between the first pixel circuit area PCA1 and the second pixel circuit area PCA2 as compared with the data line DL. For example, the first data line DL1 may be disposed farther on the left side (−x direction) of the first pixel circuit PC1 than the first driving voltage line PL1, and the second data line DL2 may be disposed farther on the right side (+x direction) of the second pixel circuit PC2 than the second driving voltage line PL2.

The second initialization voltage line VL2 may extend in the second direction (e.g., the y direction). Accordingly, the second initialization voltage line VL2 may be referred to as a vertical initialization voltage line. The second initialization voltage line VL2 may be disposed over the first pixel circuit area PCA1 and the second pixel circuit area PCA2. For example, the first pixel circuit PC1 and the second pixel circuit PC2 may share one second initialization voltage line VL2. The second initialization voltage line VL2 may be disposed on the boundary between the first pixel circuit area PCA1 and the second pixel circuit area PCA2. For example, a portion of the second initialization voltage line VL2 may be disposed in the first pixel circuit area PCA1, and another portion of the second initialization voltage line VL2 may be disposed in the second pixel circuit area PCA2. The second initialization voltage line VL2 may be connected to the seventh source region S7 of the seventh transistor T7 through the sixth-1 contact hole CNT6a, and may be connected to the third conductive pattern 1320 through the sixth-2 contact hole CNT6b.

FIG. 10 is a layout view schematically illustrating a portion of a display device according to some embodiments of the present disclosure. For example, FIG. 10 is a diagram schematically illustrating a structure in which the pixel electrode 210 is disposed on a portion of the display device shown in FIG. 4.

Referring to FIG. 10, the pixel electrode 210 may be disposed on the third conductive layer 1400. The pixel electrode 210 may include a reflective layer formed of silver (Ag), magnesium (Mg), aluminum (Al), platinum (Pt), palladium (Pd), gold (Au), nickel (Ni), neodymium (Nd), iridium (Ir), chromium (Cr), and/or a compound (e.g., alloy or combination) thereof, and a transparent or translucent electrode layer formed on the reflective layer. The transparent or translucent electrode layer may include at least one selected from the group including indium tin oxide (ITO), indium zinc oxide (IZO), zinc oxide (ZnO), indium oxide (In₂O₃), indium gallium oxide (IGO), and aluminum zinc oxide (AZO). In some embodiments, the pixel electrode 210 may include ITO/Ag/ITO. The pixel electrode 210 may include a first pixel electrode 210a, a second pixel electrode 210b, and a third pixel electrode 210c.

The first pixel electrode 210a, the second pixel electrode 210b, and the third pixel electrode 210c may be arranged in a diamond pentile array. For example, the first pixel electrode 210a and the third pixel electrode 210c may be alternately arranged in the nth row extending in the first direction (e.g., the x direction). The second pixel electrode 210b may be repeatedly arranged in the (n+1)th row extending in the first direction (e.g., the x direction) and parallel to the nth row. Based on the second direction (e.g., the y direction), the nth row and the (n+1)th row may be repeatedly arranged. For example, the second pixel electrode 210b may be disposed between the first pixel electrode 210a and the third pixel electrode 210c based on the first direction (e.g., the x direction). In other words, the second pixel electrode 210b disposed in the (n+1)th row may be alternately disposed with the first pixel electrode 210a and the third pixel electrode 210c disposed in the nth row.

A first emission area EA1 emitting red light may be defined in the first pixel electrode 210a, a second emission area EA2 emitting green light may be defined in the second pixel electrode 210b, and a third emission area EA3 emitting blue light may be defined in the third pixel electrode 210c. Each of the first pixel electrode 210a and the third pixel electrode 210c may have a substantially rectangular shape in a plan view except for a portion connected to the pixel circuit, and the second pixel electrode 210b may have a substantially chamfered rectangular shape in a plan view except for a portion connected to the pixel circuit. However, the shapes of the first pixel electrode 210a, the second pixel electrode 210b, and the third pixel electrode 210c are not limited thereto.

In some embodiments, a portion of the pixel electrode 210 may be disposed to overlap at least a portion of the third transistor T3 and the fourth transistor T4 in a plan view. For example, the pixel electrode 210 may be disposed to cover both the first sub-transistor T3-1 and the second sub-transistor T3-2. Also, the pixel electrode 210 may be disposed to cover at least one of the third sub-transistor T4-1 and the fourth sub-transistor T4-2. For example, as shown in FIG. 10, the third pixel electrode 210c may be disposed to cover all of (e.g., entirely cover) the first sub-transistor T3-1, the second sub-transistor T3-2, the third sub-transistor T4-1, and the fourth sub-transistor T4-2. The first pixel electrode 210a may be disposed to cover all of the first sub-transistor T3-1, the second sub-transistor T3-2, and the third sub-transistor T4-1.

As described above, each of the third transistor T3 and the fourth transistor T4 may include two sub-transistors. As in the case with the third and fourth transistors T3 and T4, when the gate electrodes of each of the sub-transistors are disposed to be spaced apart in a plan view with a common source-drain region therebetween, a kick-back phenomenon may occur in which the voltage rises instantaneously in the common source-drain region when the sub-transistors are switched on and off, thereby causing leakage current and a flicker phenomenon in the display device 1. For example, when a transistor located in a current leakage path is irradiated with external light or leakage light from adjacent pixels, photo-leakage currents may flow through the transistor, which can lead to a problem of intensifying the flicker phenomenon.

At this time, when the pixel electrode 210 is arranged to cover the third transistor T3 and fourth transistor T4 as in the disclosure, the pixel electrode 210 may block the light from flowing into the third transistor T3 and fourth transistor T4. Due to this light-blocking effect of the pixel electrode 210 of the display device according to some embodiments, the leakage current may be reduced, and the flicker phenomenon may be prevented or substantially reduced.

For example, the display device 1 may include not only a display element, such as a light-emitting diode ED, but also a sensing element, such as a fingerprint sensor or an illuminance sensor. The sensing element such as the fingerprint sensor may receive an optical signal provided from the outside or output an optical signal. At this time, because the pixel electrode 210 may block light incident on the sensing element, if the planar area of the pixel electrode 210 is excessively widened to cover the third and fourth transistors T3 and T4, there may be a problem in that the optical signal transmittance for sensing of the fingerprint sensor is lowered.

However, as described above, according to some embodiments, the third transistor T3 and the fourth transistor T4 of the first pixel circuit PC1 may form the flip structure (e.g., mirror image structure) with the third transistor T3 and fourth transistor T4 of the second pixel circuit PC2. That is, the distance from the boundary between the first pixel circuit area PCA1 and the second pixel circuit area PCA2 to the third transistor T3 of the first pixel circuit PCA1 may be the same as the distance from the boundary between the first pixel circuit area PCA1 and the second pixel circuit area PCA2 to the third transistor T3 of the second pixel circuit PC2. Accordingly, as the third transistor T3 of the first pixel circuit PC1 is disposed closer to the boundary, the third transistor T3 of the second pixel circuit PC2 may also disposed closer to the boundary. Thus, the distance between the third transistor T3 of the first pixel circuit PC1 and the third transistor T3 of the second pixel circuit PC2 may be shortened.

In some embodiments, if the first pixel circuit PC1 and the second pixel circuit PC2 are not formed in the flip structure but are arranged in the same structure, the closer the third transistor T3 of the first pixel circuit PC1 is disposed to the boundary, the more distant the third transistor T3 of the second pixel circuit PC2 is disposed from the boundary line. That is, if the first pixel circuit PC1 and the second pixel circuit PC2 are disposed in the same structure, the distance between the third transistor T3 of the first pixel circuit PC1 and the third transistor T3 of the second pixel circuit PC2 may not be shortened.

For example, due to the display device 1 as shown in FIG. 10 forming the first pixel circuit PC1 and the second pixel circuit PC2 in the flip structure, the distance between the third transistor T3 of the first pixel circuit PC1 and the third transistor T3 of the second pixel circuit PC2 may be reduced, and thus the area of the pixel electrode 210 for covering the third transistor T3 may be reduced. Thus, the display device 1 according to some embodiments may both minimize or substantially reduce the area of the pixel electrode 210 to increase light signal transmittance and form a flicker-resistant structure by minimizing or substantially reducing leakage current, as the pixel electrode covers the third transistor T3 and the fourth transistor T4.

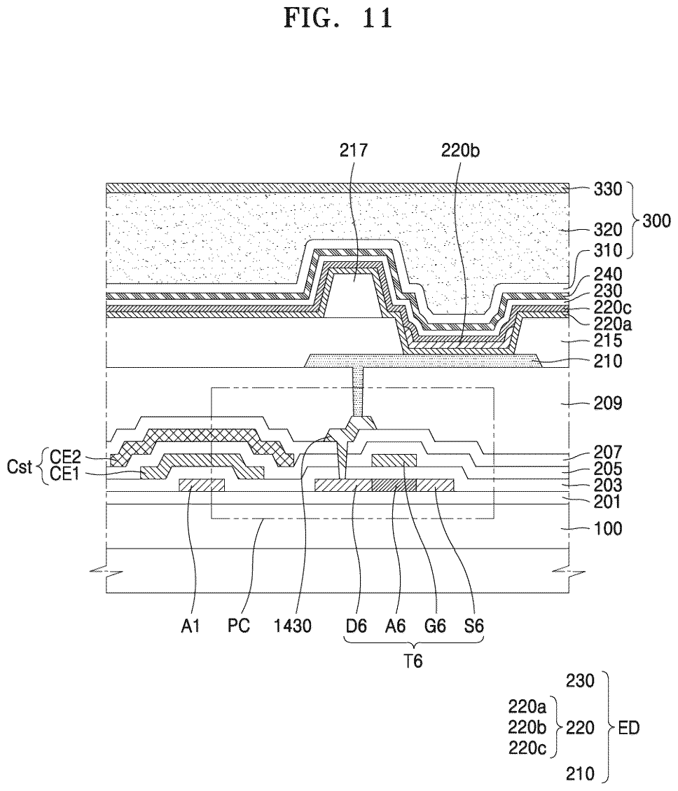

FIG. 11 is a schematic cross-sectional view illustrating a portion of a display device according to some embodiments of the present disclosure.

Referring to FIG. 11, the pixel circuit PC, the light-emitting diode ED connected to the pixel circuit PC, and an encapsulation layer 300 covering the light-emitting diode ED may be disposed on the substrate 100. The substrate 100 may include glass or a polymer resin. The substrate 100 including the polymer resin may have flexible, rollable, or bendable properties. The substrate 100 may have a multi-layered structure including a layer including the polymer resin and an inorganic layer.

A buffer layer 201 may be disposed on the substrate 100. The buffer layer 201 may reduce or prevent penetration of foreign matters, moisture, or outside air from the lower portion of the substrate 100, and may provide a flat surface on the substrate 100. The buffer layer 201 may include an inorganic material such as an oxide or nitride, an organic material, or an organic/inorganic composite, and may be formed as a single layer or multilayer structure of the inorganic material and the organic material. For example, the buffer layer 201 may have a structure in which a plurality of buffer layers are stacked, and at this time, the plurality of buffer layers may be made of different materials. For example, one of the plurality of buffer layers may comprise silicon nitride, for example, SiNₓ. Another buffer layer of the plurality of buffer layers may contain silicon oxide, for example, SiOₓ.

The first semiconductor layer 1100 (see, e.g., FIG. 5) may be disposed on the buffer layer 201. The first semiconductor layer 1100 (see, e.g., FIG. 5) may include the first channel region A1 and the sixth channel region A6. The first semiconductor layer 1100 (see, e.g., FIG. 5) may include low temperature poly-silicon (LTPS). Polysilicon materials have high electron mobility (e.g., about 100 cm²/Vs or more), low energy consumption, and excellent reliability. In some embodiments, the first semiconductor layer 1100 (see, e.g., FIG. 5) may include amorphous silicon (a-Si) and/or an oxide semiconductor material. The first semiconductor layer 1100 (see, e.g., FIG. 5) may include the channel region, the source region, and the drain region on both sides of the channel region. For example, as shown in FIG. 11, the first semiconductor layer 1100 (see, e.g., FIG. 5) may include the sixth channel region A6, the sixth source region S6, and the sixth drain region D6 on both sides of the sixth channel region A6.

A first gate insulating layer 203 may be disposed on the first semiconductor layer 1100 (see, e.g., FIG. 5). The first gate insulating layer 203 may include an inorganic material including an oxide or a nitride. For example, the first gate insulating layer 203 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), zinc oxide (ZnO₂), or the like.

The first conductive layer 1200 (see, e.g., FIG. 6) may be disposed on the first gate insulating layer 203. As shown in FIG. 11, the first conductive layer 1200 (see, e.g., FIG. 6) may include the sixth gate electrode G6 of the sixth transistor T6 and the first electrode CE1 of the storage capacitor Cst. For example, the sixth gate electrode G6 may be a portion of the light emission control line EML (see, e.g., FIG. 6), and the first electrode CE1 of the storage capacitor Cst may be a portion of the first conductive pattern 1230. The first conductive layer 1200 (see, e.g., FIG. 6) may include at least one of molybdenum (Mo), aluminum (Al), copper (Cu), and titanium (Ti), and may be formed as a single layer or multiple layers.

A second gate insulating layer 205 may be disposed on the first conductive layer 1200 (see, e.g., FIG. 6). The second gate insulating layer 205 may include an inorganic material including oxide or nitride. For example, the second gate insulating layer 205 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), zinc oxide (ZnO₂), and/or the like.

The second conductive layer 1300 (see, e.g., FIG. 8) may be disposed on the second gate insulating layer 205. The second conductive layer 1300 (see, e.g., FIG. 8) may include the second electrode CE2 of the storage capacitor Cst as shown in FIG. 11. In this case, the second electrode CE2 of the storage capacitor Cst may be a portion of the second conductive pattern 1310. The second conductive layer 1300 (see, e.g., FIG. 8) may include at least one of molybdenum (Mo), aluminum (Al), copper (Cu), and titanium (Ti), and may be formed as a single layer or multiple layers.

A first interlayer insulating layer 207 may be disposed on the second conductive layer 1300 (see, e.g., FIG. 6). The first interlayer insulating layer 207 may include an inorganic material including oxide or nitride. For example, the first interlayer insulating layer 207 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), zinc oxide (ZnO₂), or the like.

The third conductive layer 1400 (see, e.g., FIG. 9) may be disposed on the first interlayer insulating layer 207. The third conductive layer 1400 (see, e.g., FIG. 9) may include the sixth conductive pattern 1430 as shown in FIG. 11. The sixth conductive pattern 1430 may be a connection electrode connecting the pixel circuit PC and the light-emitting diode ED. The third conductive layer 1400 (see, e.g., FIG. 9) may include at least one of molybdenum (Mo), aluminum (Al), copper (Cu), and titanium (Ti), and may be formed as a single layer or multiple layers.

A first planarization layer 209 may be disposed on the third conductive layer 1400 (see, e.g., FIG. 9). The first planarization layer 209 may include an organic insulating material, such as a general-purpose polymer such as silver polymethylmethacrylate (PMMA) or polystyrene (PS), a polymer derivative having a phenolic group, an acrylic polymer, an imide polymer, an aryl ether polymer, an amide polymer, a fluorine-based polymer, a p-xylene polymer, a vinyl alcohol-based polymer, or a blend thereof. In some embodiments, the first planarization layer 209 may include polyimide. In some embodiments, in addition to the sixth conductive pattern 1430, an additional connection electrode and an additional planarization layer may be disposed to connect the pixel circuit PC and the light-emitting diode ED.

The light-emitting diode ED may be disposed on the first planarization layer 209. The light-emitting diode ED may include the pixel electrode 210, the intermediate layer 220 on the pixel electrode 210, and the opposite electrode 230 on the intermediate layer 220.

The pixel electrode 210 may be disposed on the first planarization layer 209. The pixel electrode 210 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). In some embodiments, the pixel electrode 210 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or a compound thereof. In some embodiments, the pixel electrode 210 may further include a film formed of ITO, IZO, ZnO or In2O3 above/below the above-described reflective film.

A pixel defining layer 215 may be formed on the pixel electrode 210. The pixel defining layer 215 may include an opening exposing an upper surface of the pixel electrode 210, and may cover an edge of the pixel electrode 210. The pixel defining layer 215 may include an organic insulating material. In some embodiments, the pixel defining layer 215 may include an inorganic insulating material such as silicon nitride (SiNₓ), silicon oxynitride (SiON), or silicon oxide (SiOₓ). In some embodiments, the pixel defining layer 215 may include an organic insulating material and an inorganic insulating material.

The intermediate layer 220 may include an emission layer 220b. The intermediate layer 220 may include a first functional layer 220a disposed under the emission layer 220b, and/or a second functional layer 220c disposed on the emission layer 220b. The emission layer 220b may include a polymer or a low-molecular-weight organic material that emits light of a color (e.g., a set or preset color).

The first functional layer 220a may be a single layer or multiple layers. For example, when the first functional layer 220a is formed of the polymer material, the first functional layer 220a is a single-layer structure serving as a hole transport layer (HTL), and may be formed of polyethylene dihydroxythiophene (PEDOT) or polyaniline (PAN). When the first functional layer 220a is formed of the low molecular-weight material, the first functional layer 220a may include a hole injection layer (HIL) and a hole transport layer (HTL).

In some embodiments, the second functional layer 220c may be omitted. For example, when the first functional layer 220a and the emission layer 220b are formed of the polymer material, the second functional layer 220c may be desirable. The second functional layer 220c may be a single layer or multiple layers. The second functional layer 220c may include an electron transport layer (ETL) and/or an electron injection layer (EIL).

The emission layer 220b of the intermediate layer 220 may be disposed for each pixel in the display area DA. The emission layer 220b may be patterned to correspond to the pixel electrode 210. The first functional layer 220a and/or the second functional layer 220c of the intermediate layer 220 may be integrally formed on the substrate 100.

The opposite electrode 230 may be made of a conductive material having a low work function. For example, the opposite electrode 230 may include a transparent (e.g., semitransparent) layer including silver (Ag), magnesium (Mg), aluminum (Al), platinum (Pt), palladium (Pd), gold (Au), nickel (Ni), neodymium (Nd), iridium (Cr), chromium (Li), calcium (Ca), or alloys thereof. For example, the opposite electrode 230 may further include a layer such as ITO, IZO, ZnO or In2O3 on the transparent layer including the above-described material. The opposite electrode 230 may be integrally formed on the substrate 100. The first functional layer 220a, the second functional layer 220c, and the opposite electrode 230 may be formed by a thermal vapor deposition method.

A capping layer 240 may be positioned on the opposite electrode 230. For example, the capping layer 240 may include LiF, and may be formed by a thermal deposition method. In some embodiments, the capping layer 240 may be omitted.

A spacer 217 may be formed on the pixel defining layer 215. The spacer 217 may include an organic insulating material such as polyimide. In some embodiments, the spacer 217 may include an inorganic insulating material, or may include an organic insulating material and an inorganic insulating material.

The spacer 217 may include a material different from that of the pixel defining layer 215, or may include the same material as that of the pixel defining layer 215. For example, the pixel defining layer 215 and the spacer 217 may be formed together in a mask process using a halftone mask. In some embodiments, the pixel defining layer 215 and the spacer 217 may include polyimide.

The light-emitting diode ED may be covered with an encapsulation member. FIG. 11 illustrates that the light-emitting diode ED is covered with the encapsulation member such as the encapsulation layer 300, but the disclosure is not limited thereto. In some embodiments, the light-emitting diode ED may be shielded from the outside air by the encapsulation member such as an upper substrate and frit.

The encapsulation layer 300 may include at least one organic encapsulation layer and at least one inorganic encapsulation layer, and FIG. 11 illustrates that the encapsulation layer 300 includes a first inorganic encapsulation layer 310, a second inorganic encapsulation layer 330, and an organic encapsulation layer 320 therebetween. In some embodiments, the number of organic encapsulation layers, the number of inorganic encapsulation layers, and the stacking order may be changed.

The first inorganic encapsulation layer 310 and the second inorganic encapsulation layer 330 may include at least one inorganic material, such as aluminum oxide, titanium oxide, tantalum oxide, hafnium oxide, zinc oxide, silicon oxide, silicon nitride, and silicon oxynitride. The first inorganic encapsulation layer 310 and the second inorganic encapsulation layer 330 may be a single layer or multiple layers including the above-described materials.

The organic encapsulation layer 320 may include a monomer-based material or a polymer-based material. Polymer-based materials may include acrylic resin, epoxy resin, polyimide, and polyethylene. In some embodiments, the organic encapsulation layer 320 may include acrylate.

The display apparatus according to the embodiment may be applied to various electronic apparatuses. An electronic apparatus according to an embodiment of the present disclosure may include the display apparatus (e.g., the display apparatus of FIG. 1) described above, and may further include modules or apparatuses having additional functions in addition to the display apparatus.

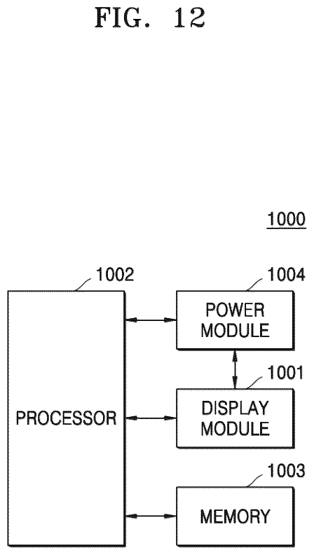

FIG. 12 is a block diagram of an electronic apparatus according to some embodiments of the present disclosure.

Referring to FIG. 12, an electronic apparatus 1000 according to an embodiment may include a display module 1001, a processor 1002, a memory 1003, and a power module 1004.

The processor 1002 may include at least one of a central processing unit (CPU), an application processor (AP), a graphic processing unit (GPU), a communication processor (CP), an image signal processor (ISP), and a controller.

The memory 1003 may store data information necessary for the operation of the processor 1002 or the display module 1001. When the processor 1002 executes an application stored in the memory 1003, an image data signal and/or an input control signal may be transmitted to the display module 1001, and the display module 1001 may process a signal received and output image information through a display screen.

The power module 1004 may include a power supply module such as a power adapter or a battery device, and a power conversion module that converts the power supplied by the power supply module to generate power necessary for the operation of the electronic apparatus 1000.

At least one of the components of the electronic apparatus 1000 described above may be included in the display apparatus according to the embodiments described above. In addition, a part among the individual modules functionally included in one module may be included in the display apparatus, and another part may be provided separately from the display apparatus. For example, the display apparatus may include the display module 1001, and the processor 1002, the memory 1003, and the power module 1004 may be provided in the form of other apparatuses within the electronic apparatus 1000 except for the display apparatus.

In an embodiment, the display module 1001 included in the display apparatus may drive based on the image data signal and the input control signal received from the processor 1002.

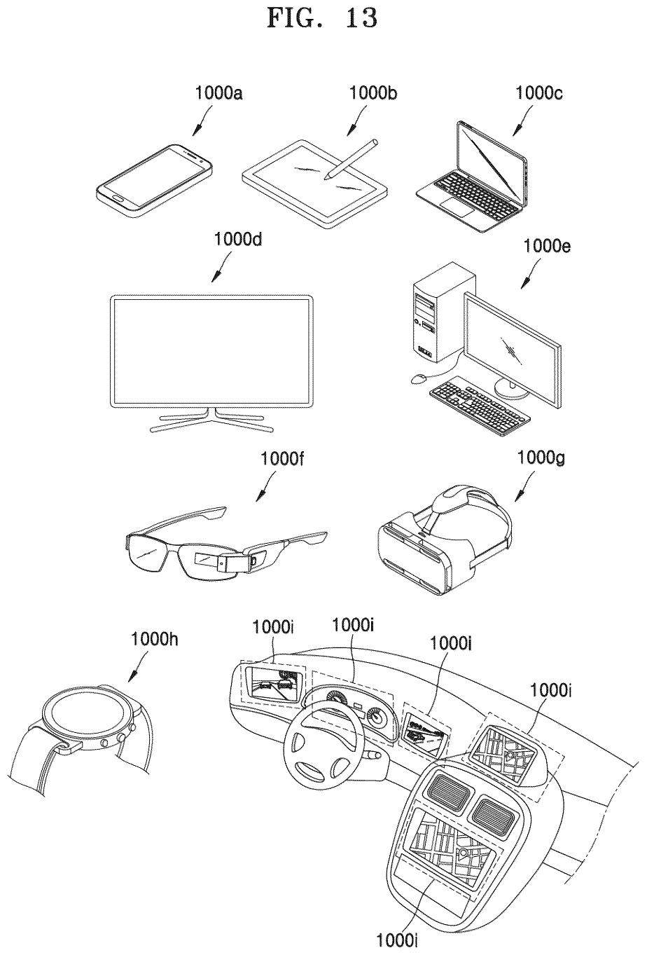

FIG. 13 is schematic diagrams of electronic apparatuses according to various embodiments.

Referring to FIG. 13, various electronic apparatuses to which display apparatuses according to embodiments are applied may include not only image display electronic apparatuses such as a smart phone 1000a, a tablet PC 1000b, a laptop 1000c, a TV 1000d, and a desk monitor 1000e, but also a wearable electronic device including display modules such as smart glasses 1000f, a head mounted display 1000g, and a smart watch 1000h, and a vehicle electronic device 1000i including a dashboard, a center fascia, and display modules such as a CID (Center Information Display) and a room mirror display disposed in the dashboard.

The display device according to some embodiments may have improved display quality and a more robust structure. However, this is merely an example, and the scope of the disclosure is not limited thereto.

Although the disclosure is described with reference to embodiments illustrated in the drawings, this is only an example, and those of ordinary skill in the art will understand that various modifications of the embodiments may be made therefrom. Therefore, the true technical protection scope of the disclosure should be determined by the technical idea of the appended patent claims.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims and equivalents thereof.

What is claimed is:

1. A display device comprising:
a substrate comprising a first pixel circuit area and a second pixel circuit area adjacent to the first pixel circuit area along a first direction;
a pixel circuit on the substrate and comprising a first pixel circuit in the first pixel circuit area, and a second pixel circuit in the second pixel circuit area; and
a light-emitting element connected to the pixel circuit,
wherein each of the first pixel circuit and the second pixel circuit comprises:
a first transistor electrically connected to a driving voltage line and the light-emitting element and configured to control current supplied to the light-emitting element;
a second transistor electrically connected to a data line and a first terminal of the first transistor;
a third transistor electrically connected to a gate of the first transistor and a second terminal of the first transistor; and
a fourth transistor electrically connected to the gate of the first transistor and a first initialization voltage line; and
wherein, in a plan view, the third transistor of the first pixel circuit and the fourth transistor of the first pixel circuit are line-symmetrical to the third transistor of the second pixel circuit and the fourth transistor of the second pixel circuit, with respect to an imaginary straight line extending in a second direction intersecting the first direction.

2. The display device of claim 1, a second initialization voltage line extending along the second direction,
wherein the driving voltage line and the data line are arranged in each of the first pixel circuit area and the second pixel circuit area and extend along the second direction,
wherein the second initialization voltage line is on a boundary between the first pixel circuit area and the second pixel circuit area, and
wherein a portion of the second initialization voltage line is in the first pixel circuit area, and another portion of the second initialization voltage line is in the second pixel circuit area.

3. The display device of claim 1, further comprising a first gate line connected to a gate of the third transistor,
wherein the first gate line comprises:
a first trunk portion extending along the first direction;
a first branch portion branched from the first trunk portion within the first pixel circuit area and extending in the second direction; and
a second branch portion branched from the first trunk portion within the second pixel circuit area and extending in the second direction.

4. The display device of claim 3, wherein a distance from a boundary between the first pixel circuit area and the second pixel circuit area to the first branch portion is about the same as a distance from the boundary between the first pixel circuit area and the second pixel circuit area to the second branch portion.

5. The display device of claim 3, wherein the third transistor comprises a first sub-transistor and a second sub-transistor connected in series,
wherein a gate of the first sub-transistor is formed in a partial area of the first branch portion or a partial area of the second branch portion, and
wherein a gate of the second sub-transistor is formed in a partial area of the first trunk portion.

6. The display device of claim 1, further comprising a second gate line connected to a gate of the fourth transistor, wherein the second gate line comprises:
a second trunk portion extending along the first direction;
a third branch portion branched from the second trunk portion within the first pixel circuit area and extending in the second direction; and
a fourth branch portion branched from the second trunk portion within the second pixel circuit area and extending in the second direction.

7. The display device of claim 6, wherein a distance from a boundary between the first pixel circuit area and the second pixel circuit area to the third branch portion is about the same as a distance from the boundary between the first pixel circuit area and the second pixel circuit area to the fourth branch portion.

8. The display device of claim 6, wherein the fourth transistor comprises a third sub-transistor and a fourth sub-transistor connected in series,
wherein a gate of the third sub-transistor is formed in a partial area of the second trunk portion, and
wherein a gate of the fourth sub-transistor is formed in a partial area of the third branch portion or a partial area of the fourth branch portion.

9. The display device of claim 1, wherein the light-emitting element comprises a pixel electrode, an intermediate layer on the pixel electrode, and an opposite electrode on the intermediate layer, and
wherein in a plan view, the pixel electrode overlaps at least a portion of the third transistor and the fourth transistor.

10. The display device of claim 9, wherein the light-emitting element comprises a first light-emitting diode, a second light-emitting diode, and a third light-emitting diode emitting light of different colors,
wherein the first light-emitting diode and the third light-emitting diode are arranged alternately in a first row extending in the first direction,
wherein the second light-emitting diode is repeatedly arranged in a second row parallel to the first row, and is arranged between the first light-emitting diode and the third light-emitting diode with respect to the first direction, and
wherein the pixel electrode that at least partially overlaps with the third transistor and the fourth transistor is a pixel electrode of the first light-emitting diode or a pixel electrode of the third light-emitting diode.

11. The display device of claim 1, wherein, a first semiconductor layer of the first transistor, a second semiconductor layer of the second transistor, a third semiconductor layer of the third transistor, and a fourth semiconductor layer of the fourth transistor are integrally formed.

12. A display device comprising:
a substrate comprising a first pixel circuit area and a second pixel circuit area arranged adjacent to the first pixel circuit area along a first direction;
a first gate line on the substrate and extending along the first direction;
a driving voltage line extending along a second direction intersecting the first direction;
a pixel circuit comprising a first pixel circuit in the first pixel circuit area, and a second pixel circuit in the second pixel circuit area; and
a light-emitting element connected to the pixel circuit and comprising a pixel electrode, an intermediate layer on the pixel electrode, and an opposite electrode on the intermediate layer;
wherein each of the first pixel circuit and the second pixel circuit comprises:
a driving transistor electrically connected to the driving voltage line and the light-emitting element; and
a compensation transistor comprising a gate connected to the first gate line, and connected to a gate of the driving transistor and a first terminal of the driving transistor,
wherein, in a plan view, the compensation transistor of the first pixel circuit and the compensation transistor of the second pixel circuit are line-symmetrical to each other with respect to an imaginary straight line extending in the second direction, and
a partial area of the pixel electrode overlaps with the compensation transistor.

13. The display device of claim 12, wherein the first gate line comprises:
a first trunk portion extending along the first direction;
a first branch portion branched from the first trunk portion within the first pixel circuit area and extending in the second direction; and
a second branch portion branched from the first trunk portion within the second pixel circuit area and extending in the second direction.

14. The display device of claim 13, wherein a distance from a boundary between the first pixel circuit area and the second pixel circuit area to the first branch portion is about the same as a distance from the boundary between the first pixel circuit area and the second pixel circuit area to the second branch portion.

15. The display device of the claim 13, wherein the compensation transistor comprises a first sub-transistor and a second sub-transistor connected in series,
wherein a gate of the first sub-transistor is formed in a partial area of the first branch portion or a partial area of the second branch portion,
wherein a gate of the second sub-transistor is formed in a partial area of the first trunk portion, and
wherein a partial area of the pixel electrode covers both the first sub-transistor and the second sub-transistor.

16. The display device of claim 12, further comprising a second gate line and a horizontal initialization voltage line extending along the first direction,
wherein each of the first pixel circuit and the second pixel circuit further comprises an initialization transistor comprising a gate connected to the second gate line and electrically connected to the gate of the driving transistor and the horizontal initialization voltage line, and
wherein in a plan view, the initialization transistor of the first pixel circuit and the initialization transistor of the second pixel circuit are line-symmetrical to each other with respect to the imaginary straight line extending in the second direction.

17. The display device of claim 16, wherein the second gate line comprises:
a second trunk portion extending along the first direction;
a third branch portion branched from the second trunk portion within the first pixel circuit area and extending in the second direction; and
a fourth branch portion branched from the second trunk portion within the second pixel circuit area and extending in the second direction.

18. The display device of claim 17, wherein a distance from a boundary between the first pixel circuit area and the second pixel circuit area to the third branch portion is about the same as a distance from the boundary between the first pixel circuit area and the second pixel circuit area to the fourth branch portion.

19. The display device of claim 17, wherein the initialization transistor comprises a third sub-transistor and a fourth sub-transistor connected in series,
wherein a gate of the third sub-transistor is formed in a partial area of the second trunk portion,
wherein a gate of the fourth sub-transistor is formed in a partial area of the third branch portion or a partial area of the fourth branch portion, and
wherein a partial area of the pixel electrode covers at least one of the third sub-transistor and the fourth sub-transistor.

20. An electronic device comprising:
an input module configured to receive input data from a user;
a memory configured to store the input data;
a processor configured to perform computations based on the input data and provide output data; and
a display module configured to display an image to the user based, in part, on the input data and the output data, the display module comprising:
a substrate comprising a first pixel circuit area and a second pixel circuit area adjacent to the first pixel circuit area along a first direction;
a pixel circuit on the substrate and comprising a first pixel circuit in the first pixel circuit area, and a second pixel circuit in the second pixel circuit area; and
a light-emitting element connected to the pixel circuit,
wherein each of the first pixel circuit and the second pixel circuit comprises:
a first transistor electrically connected to a driving voltage line and the light-emitting element and configured to control current supplied to the light-emitting element;
a second transistor electrically connected to a data line and a first terminal of the first transistor;
a third transistor electrically connected to a gate of the first transistor and a second terminal of the first transistor; and
a fourth transistor electrically connected to the gate of the first transistor and a first initialization voltage line; and
wherein, in a plan view, the third transistor of the first pixel circuit and the fourth transistor of the first pixel circuit are line-symmetrical to the third transistor of the second pixel circuit and the fourth transistor of the second pixel circuit, with respect to an imaginary straight line extending in a second direction intersecting the first direction.
